(19) United States
(12) Patent Application Publication
(10) Pub. No.: US 2026/0030421 A1
(43) Pub. Date: Jan. 29, 2026

(54) SYSTEM AND METHOD FOR DEVELOPING AND EVALUATING PROTOTYPE PARAMETERIZED CELLS

(71) Applicant: GlobalFoundries U.S. Inc., Malta, NY (US)

(72) Inventors: Aleks-Martin Konstantinov Lakovski, Sofia (BG); Simona Milenova Dimitrova, Sofia (BG); Romain H.A. Feuillette, Williston, VT (US); Bradley A. Orner, Ben Lomond, CA (US); Kiril Ivanov Ivanov, Sofia (BG)

(21) Appl. No.: 18/787,137

(22) Filed: Jul. 29, 2024

(51) Int. Cl. G06F 30/327; G06F 30/398

(52) U.S. Cl. CPC G06F 30/327; G06F 30/398

(57) ABSTRACT

Disclosed are a system, method, and computer program product for developing and evaluating a prototype parameterized cell (P-PCELL) for a specific integrated circuit component. The P-PCELL is developed using multiple graphic design system (GDS) files for the component and a mapping file. Optionally, P-PCELL development is performed using a first machine learning model. Optionally, the P-PCELL is also evaluated based on test feedback acquired through user-testing including, for example, design rule checking (DRC) errors. Updates (e.g., design manual and/or parameter range updates) can be developed given the DRC errors. Optionally, development of the updates is performed using a second machine learning model. P-PCELL evaluation can further include determining P-PCELL code functionality, de-bugging the P-PCELL code, detecting any irregularities in the P-PCELL (e.g., based on a comparison of user-customized configurations with specifications and the GDS files) and correcting such irregularities.

### BACKGROUND

The present disclosure relates to process design kits (PDKs) and, more particularly, to a system and method for developing and evaluating a prototype parameterized cell (PCELL) for a specific integrated circuit (IC) component before including parameterized cell (PCELL) for that specific IC component in a PCELL library of a process design kit (PDK).

A process design kit (PDK) is a set of electronic files including both data and script files. It is typically developed by a semiconductor foundry for its customers in order to facilitate design of integrated circuits (ICs) at a specific technology node supported by the foundry. The electronic files are accessible by one or more electronic design automation (EDA) tools executed on a customer's computer network (e.g., on a computer-aided design (CAD) system) at different stages in the design flow. Exemplary PDK electronic files can include, but are not limited to, simulation models, symbols and technology files for the specific technology node, a parameterized cell (PCELL) library, and design rule decks and associated initialization scripts for the different stages of the design flow (e.g., for floorplanning, power planning, input/output pin placement, library element placement, clock planning, wire routing, a layout versus schematic (LVS) check, 3D emulation, simulations, etc.).

A PCELL (also referred to in the art as a template cell) represents a specific IC component (e.g., a specific device or interconnected group of devices), which can be selected from a PCELL library of a PDK for inclusion in an IC design and which has user-customizable parameters. To generate a PCELL, PCELL developers employ inputs from multiple sources. Finalizing the code for the PCELL can take a significant amount of time. This can delay detection of problems associated with some of the available PCELL configurations during downstream design processes including, but not limited to, design rule checking (DRC) processes, layout versus schematic (LVS) checking, design manual (DM) checking, etc. As a result, developers of PDKs that will include a given PCELL may need to modify that PCELL without having its source code (e.g., by reverse engineering). However, the exponential complexity of all possible PCELL configurations may make such reverse engineering extremely difficult.

### SUMMARY

Disclosed herein are embodiments of a computer system. The computer system can include a processor. The computer system can further include at least one storage medium readable by the processor. The storage medium can store a mapping file and multiple different graphic design system (GDS) files for a specific integrated circuit component. The storage medium can also store a program of instructions, which is executable by the processor and which can cause the processor to perform a method including developing a prototype parameterized cell (P-PCELL) for the specific integrated circuit component using the GDS files and the mapping file.

Also disclosed herein are embodiments of a computer-implemented method. The method can include accessing, by a processor from at least one storage medium, a mapping file and multiple different graphic design system (GDS) files for a specific integrated circuit component. The method can further include developing, by the processor, a prototype parameterized cell for the specific integrated circuit component, wherein the prototype parameterized cell is developed using the GDS files and the mapping file.

Also disclosed herein are embodiments of a computer program product. The computer program product can include a non-transitory computer readable storage medium having program instructions embodied therewith (e.g., stored thereon). These program instructions can be executable by a processor to cause the processor to perform the above-described method.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram illustrating an integrated circuit (IC) design environment;

FIG. 2 is a schematic diagram illustrating an embodiment of a computer system that can be incorporated into the design environment of FIG. 1 for process design kit (PDK) development;

FIG. 3 is a flow diagram illustrating an embodiment of a method;

FIG. 4 is a flow diagram illustrating an embodiment of process 302 of FIG. 3;

FIG. 5 is a flow diagram illustrating an embodiment of process 304 of FIG. 3; and

FIG. 6 is a schematic diagram illustrating an example hardware environment for implementing aspects of the disclosed embodiments.

### DETAILED DESCRIPTION

As mentioned above, a parameterized cell (PCELL) (also referred to in the art as a template cell) represents a specific IC component (e.g., a specific device or interconnected group of devices), which can be selected from a PCELL library of a PDK for inclusion in an IC design and which has user-customizable parameters. To generate a PCELL, PCELL developers employ inputs from multiple sources and finalizing the code for the PCELL can take a significant amount of time. This can delay detection of problems associated with some of the available PCELL configurations during downstream design processes including, but not limited to, design rule checking (DRC) processes, layout versus schematic (LVS) checking, design manual (DM) checking, etc. As a result, developers of PDKs that will include a given PCELL may need to modify that PCELL without having its source code (e.g., by reverse engineering). However, the exponential complexity of all possible PCELL configurations may make such reverse engineering extremely difficult.

In view of the foregoing, disclosed herein are embodiments of a computer system, a computer-implemented method, and a computer program product for developing and evaluating a prototype parameterized cell (P-PCELL) for a specific integrated circuit (IC) component prior to including a PCELL for that specific IC component in a PCELL library of a process design kit (PDK). More particularly, in the disclosed embodiments, a P-PCELL for a specific IC component (e.g., for a specific device or interconnected group of devices) can be developed using multiple different graphic design system (GDS) files (e.g., GDSII files) for the IC component and on a mapping file for the process technology at issue. Such a P-PCELL can include, for example, code and component description format (CDF) files including callbacks. Optionally, P-PCELL development can be performed using a first machine learning model. Such a P-PCELL can subsequently be evaluated based on test feedback acquired through user-testing. The test feedback can include, for example, detected design rule checking (DRC) errors. These detected DRC errors can be used to develop P-PCELL updates (e.g., design manual (DM) updates and/or parameter range updates). Optionally, this portion of the evaluation process (i.e., detection of DRC errors and development of updates) can be performed using a second machine learning model. Optionally, the evaluation process can further include determining P-PCELL code functionality, de-bugging the P-PCELL code (as necessary), detecting any irregularities in the P-PCELL (based on a comparison of user-customized configurations of the specific IC component with specifications and the GDS files for the specific IC component), and correcting any such irregularities prior to inclusion of a PCELL for the specific IC component in the PCELL library.

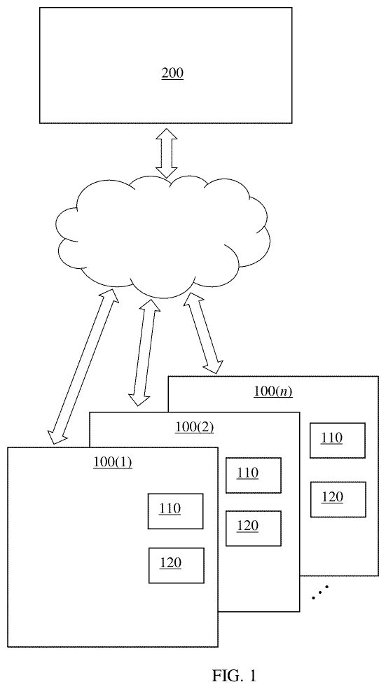

FIG. 1 is a schematic diagram illustrating an integrated circuit (IC) design environment within which the disclosed embodiments of the present invention can be implemented. Specifically, this IC design environment includes a computer system 200 (e.g., of a semiconductor foundry). This computer system 200 can be configured for development, revisioning, etc. of a process design kit (PDK) 110. PDK 110 can be associated with a specific processing technology supported by the semiconductor foundry (also referred to herein as a technology node or process node). Those skilled in the art will recognize that a technology node is typically identified in nanometers (e.g., a 45 nm, 32 nm, 22 nm, 14 nm, etc.), thereby indicating the size of the semiconductor features that can be formed on a semiconductor wafer at the foundry using the technology. The technology node may also indicate the type of wafer, such as a silicon-on-insulator (SOI) wafer (e.g., 45 nm SOI, 32 nm SOI, 22 nm SOI, etc.), bulk silicon wafer, etc. PDK 110 can include, for example, conventional PDK components (e.g., a parameterized cell (PCELL) library, a graphic user interface (GUI), design data and script files including simulation models, symbols and technology files for the specific technology node, design rule decks and associated initialization scripts, etc.). Such a PDK 110 can be supplied by the semiconductor foundry to one or more computer-aided design (CAD) systems 100(1)-100(n) (e.g., of customer(s) of the semiconductor foundry). CAD system(s) 100(1)-100(n) can be configured to use PDK 110 in conjunction with local electronic design automation (EDA) tools 120 to generate IC designs. An IC design generated in this manner can be sent back to the semiconductor foundry and ICs can be manufactured by the semiconductor foundry according to the design. PDK-based design improves yield during manufacturing because the PDK is foundry-specific and accounts for process variations.

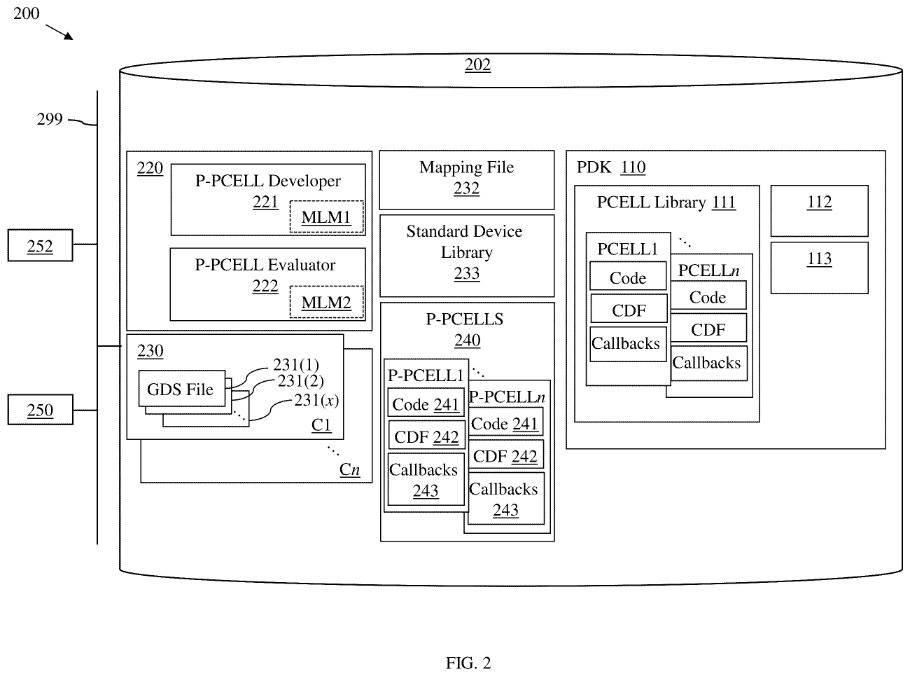

FIG. 2 is a schematic diagram illustrating a disclosed embodiment of a computer system 200 that can be incorporated into the design environment of FIG. 1. As mentioned above, computer system 200 can be configured for development, revisioning, etc., of a PDK 110. Development and revisioning of PDK 110 can include generation of PCELLs for different integrated circuit (IC) components (e.g., different devices and/or different groups of interconnected devices) for a PCELL library 111 of PDK 110. In the disclosed embodiments, generation of the PCELL for a specific IC component can include development and evaluation of a prototype parameterized cell (P-PCELL) for that specific IC component.

More particularly, computer system 200 can include, but is not limited to, at least one processor 250, at least one display 252, and at least one computer readable storage medium 202 readable by processor(s) 250. The various components of computer system 200 (i.e., processor(s) 250, display(s) 252, storage mediums(s) 202, etc.) can be interconnected over a system bus 299, as illustrated, and/or over a wired or wireless network (not shown). Furthermore, the various components of computer system 200 can be co-located. Alternatively, computer system 200 can be a client-server system with a central server and multiple networked workstations. Alternatively, computer system 200 can be a distributed system whose components are distributed across different networked computers. In any case, for purposes of illustration, computer system 200 is illustrated in FIG. 2 and described below as if it incorporates only a single processor 250, a single display 252, and a single storage medium 202. However, it should be understood that, alternatively, computer system 200 can incorporate any number of one or more processors 250 for performing one or more of the different steps in the disclosed method, any number of one or more displays 252, and any number of one or more storage mediums for storing the data and tools that are employed in the disclosed method.

Storage medium 202 can store a PDK 110. PDK 110 can include, for example, a PCELL library 111. PCELL library 111 can include one or more PCELLs (PCELL1-PCELLn). Each PCELL can represent a specific IC component. The specific IC component can include one device (e.g., a transistor, capacitor, resistor, etc.) or a group of interconnected devices (e.g., a logic gate, etc.). Each PCELL can include an executable parameter customization program (also referred to as a parameter customization script) (i.e., PCELL code). The PCELL code allows one or more geometric parameters of one or more devices of the specific IC component represented by the PCELL to be user-customized (e.g., through a GUI 112). Each PCELL can also include component description format (CDF) files. Those skilled in the art will recognize that CDF files for a PCELL can indicate geometric parameters of individual features of device(s) in the PCELL, attributes of the geometric parameters, and callbacks. Callbacks refer to relationships between specific parameters. PDK 110 can also include other design data and script files 113 including simulation models, symbols and technology files for the specific technology node, design rule decks and associated initialization scripts, etc., which can be employed by EDA tools of a CAD system during IC design.

Storage medium 202 can also store programs 220 of instruction (i.e., software), executable by processor 250 to cause performance of the disclosed method. Programs 220 can include, but are not limited to, a prototype parameterized cell (P-PCELL) developer 221 and a P-PCELL evaluator 222. P-PCELL developer 221 and P-PCELL evaluator 222 can be discrete programs, as illustrated. Alternatively, they can be combined in a single program.

Storage medium 202 can further store additional processing technology-specific information. For example, storage medium 202 can store sets 230 of graphic design system (GDS) files (e.g., GDSII files) for various integrated circuit (IC) components C1-Cn available at the technology node. Each set 230 can, for example, include multiple different GDS files 231(1)-231(x) associated with the same specific IC component (i.e., associated with the same device or group of interconnected devices). Those skilled in the art will recognize that a GDS file refers to a binary file format used in IC design to represent the layout of an IC. Information included in a GDS file includes physical layers, shapes within the layers, and interconnections therebetween. Generally, layers refer to different processing layers included in an IC component and shapes correspond to geometric shapes that correspond to specific patterns in the layers. Storage medium 202 can further store a mapping file 232 (also referred to herein as a layer mapping file or layer map file) for the technology node. This mapping file 232 can be a text file that maps out all layers in the processing technology. Storage medium 202 can further store a device library 233 including specifications for different devices.

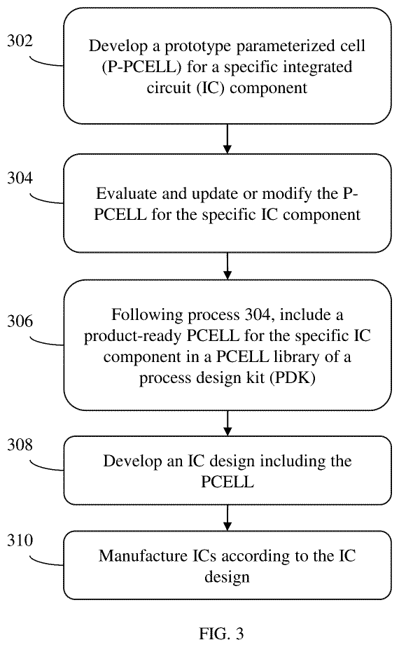

FIG. 3 is a flow diagram illustrating, generally, the disclosed method. The method can include developing a prototype parameterized cell (P-PCELL) for a specific IC component (e.g., see P-PCELL developer 221 and process 302). The method can further include evaluating the P-PCELL for the specific IC component and, based on results of the evaluation, updating or modifying the P-PCELL, as necessary (e.g., see P-PCELL evaluator 222 and process 304). Once the P-PCELL for the specific IC component has been developed, evaluated and, if necessary, updated or modified, the P-PCELL can be deemed product-ready (i.e., ready for inclusion in a PDK) and added to PCELL library 111 of PDK 110 (see process 306). As mentioned above, PDK 110 can be supplied to CAD system(s) 100(1)-100(n) and used in conjunction with local EDA tools 120 to design ICs. Thus, a PCELL generated according to the method of FIG. 3 can be selected for inclusion in an IC design and ICs can be manufactured according to that IC design (see processes 308-310).

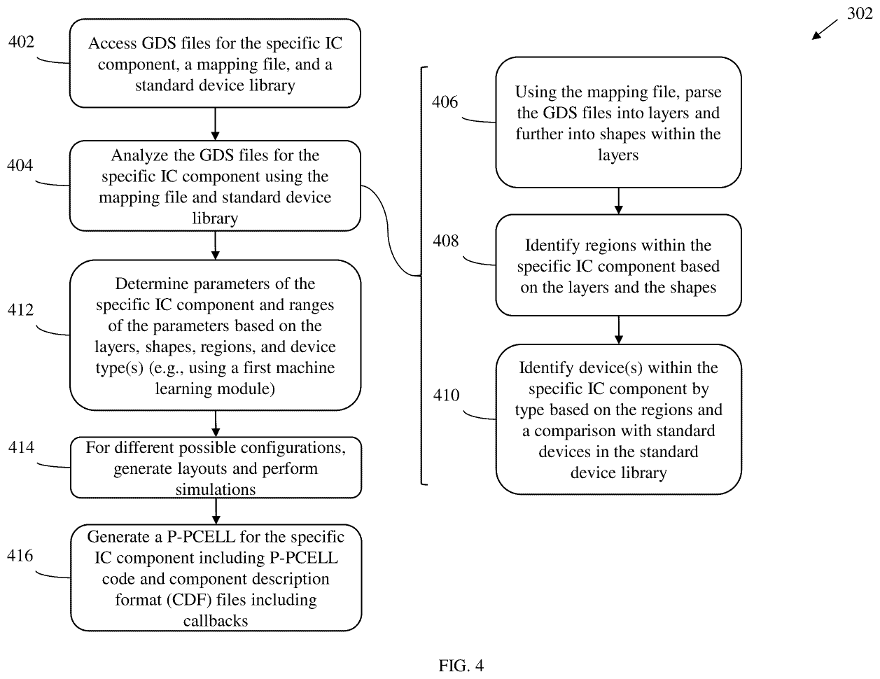

FIG. 4 is a flow diagram illustrating, in greater detail, process 302 of FIG. 3. For purposes of illustration, process 302 is described herein with respect to development of a P-PCELL for a specific IC component (C1) (e.g., by processor 250 executing P-PCELL developer 221). Referring to FIG. 4 in combination with FIG. 2, to develop the P-PCELL for C1 at process 302, the set 230 of GDS files (e.g., GDS files 231(1)-231(x) associated with C1, mapping file 232, and device library 233 can be accessed (see process 402). The total number (x) of GDS files can include any number of two or more GDS files representing two or more different instances of C1 having at least one parameter that is variable. Next, the GDS files 231(1)-231(x) can be analyzed (see process 404). Specifically, using mapping file 232, GDS files 231(1)-231(x) for C1 can be parsed into layers and shapes within the layers (see process 406). That is, in conjunction with mapping file 232 and given the multiple GDS files 231(1)-231(x), various layers in C1 and shapes within those layers can be identified. Then, based on the layers and the shapes within the layers included in C1, specific regions of C1 can be identified (see process 408). For purposes of this disclosure, specific regions of an IC component can include structural elements of device(s) in the IC component. For example, if C1 includes a field effect transistor, regions (or elements) thereof can include a gate structure, gate sidewall spacers, an active device region, a channel region, source/drain regions, etc. Then, the regions of C1 as identified at process 408 can be compared to regions of known devices in device library 233 in order to specifically identify each device in C1 by type (e.g., field effect transistor, bipolar junction transistor, heterojunction bipolar transistor, PN diode, PIN diode, etc.) or, if applicable, the IC component as a whole by type of group of interconnected devices (e.g., AND gate, NAND gate, etc.) (see process 410).

Subsequently, geometric parameters of C1 and ranges for those geometric parameters can be determined based on the layers, shapes within the layers, regions, identified device(s) of the IC component C1 (see process 412). For example, if C1 is a field effect transistor, parameters could include number of gate fingers, channel length, channel width, source-side gate sidewall spacer width, drain-side gate sidewall spacer width, etc. Furthermore, as indicated by the sizes and geometry of the shapes illustrated in different GDS files, attributes associated any one or more of these parameters could be variable within some range. For example, the number of gate fingers could be any number within a range from a minimum number to a maximum number, the channel width could be any width within a range between a minimum width to a maximum width, the channel length could be any length within a range between a minimum length and a maximum length, etc. Optionally, process 412 could be performed using a first machine learning model (MLM1). MLM1 can, for example, be generated using a first ML training set, which includes data and other information acquired through previous development and, optionally, evaluation (as discussed in greater detail below) of different P-PCELLS with similar layers, shapes within layers, and regions and, thus, similar parameters. Those skilled in the art will recognize that machine learning (ML) is a component of artificial intelligence (AI) in which statistical algorithms can be employed to learn from previously generated data and generalize to unseen data. Techniques (including, but not limited to, supervised learning, unsupervised learning, and/or reinforced learning) for generating ML models based on a training set of data are known in the art and, thus, the details thereof have been omitted from this specification in order to allow the reader to focus on the salient aspects of the disclosed embodiments.

Given the geometric parameters of C1 and the ranges thereof determined at process 412, layouts for different possible configurations could be generated and simulations of C1 could be performed based on the layouts (see process 414). Based on the results of processes 404-414 and user inputs, a P-PCELL for C1 can be generated. (see process 416). P-PCELLs 240 for different IC components can, for example, be stored in storage medium 202. Each P-PCELL can include P-PCELL code 241 (i.e., an executable parameter customization program, which allows one or more geometric parameters of one or more devices of C1 represented by the P-PCELL to be user-customized through a graphic user interface (GUI)). The P-PCELL can also include component description format (CDF) files 242. CDF files 242 for the P-PCELL can indicate geometric parameters of individual features within C1, attributes of the parameters, and also callbacks 243 indicating (i.e., define) relationships between different geometric parameters.

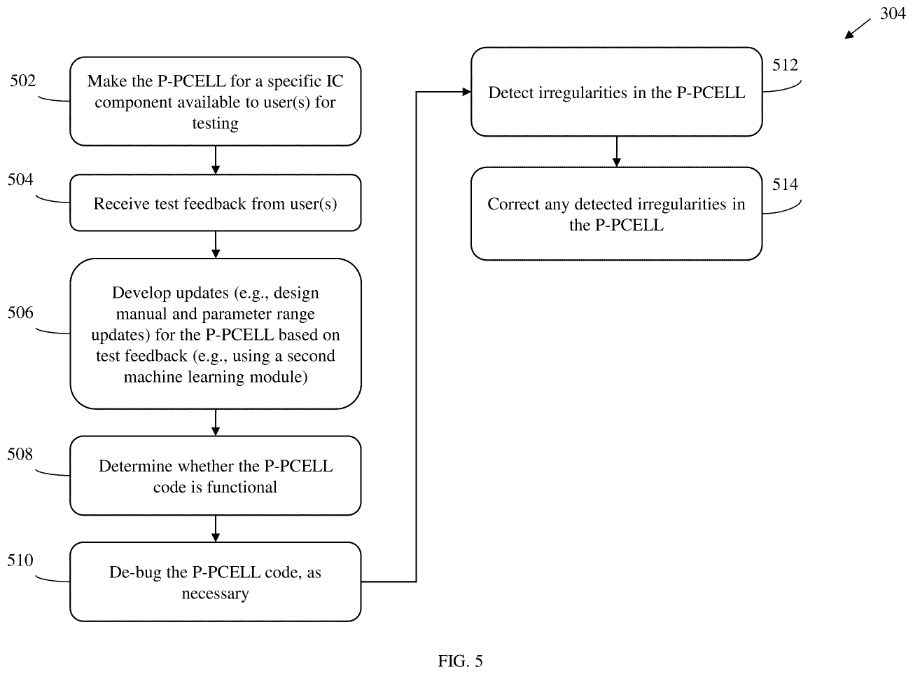

As mentioned above, instead of being inserted immediately into PDK 110, each P-PCELL (e.g., P-PCELL for C1) can be evaluated and updated or modified, as necessary at process 304 of FIG. 3. FIG. 5 is a flow diagram illustrating, in greater detail, process 304 of FIG. 3. For purposes of illustration, process 304 is described herein with respect to evaluation of the P-PCELL for C1 (e.g., by processor 250 executing P-PCELL evaluator 222). Referring to FIG. 5 in combination with FIG. 2, the P-PCELL for C1 (including the P-PCELL code 241 and CDF files 242 including callbacks 243) can be made available for testing by one or more users and, particularly, by one or more IC component designer(s) for the semiconductor foundry that is developing PDK 110 (also referred to herein as device owners) (see process 502). For example, a notification can be output to user(s) (e.g., via electronic mail (email), message, etc.) indicating that the P-PCELL for C1 is available for testing. User(s) can employ this P-PCELL to generate design layouts for various different user-customized configurations of C1. User(s) can further analyze each user-customized configuration including, but not limited to, simulating performance and performing design rule checking (DRC) to verify whether C1 meets the constraints imposed by the process technology when it has a particular user-customized configuration. Test feedback for the P-PCELL for C1 can be received by processor 250 and stored in storage medium 202 (see process 504). Such feedback can, for example, indicate any DRC errors detected during user testing. Based on the test feedback, required updates or modifications to the P-PCELL for C1 can be developed (see process 506). The required updates or modifications can include, but are not limited to, design manual (DM) and/or parameter range updates. Optionally, process 506 could be performed using a second machine learning model (MLM2). MLM2 can, for example, be generated using a second ML training set, which includes data and other information acquired through previous evaluation of different P-PCELLs to identify required updates based on test feedback. As mentioned above with regard to MLM1, those skilled in the art will recognize that machine learning (ML) is a component of artificial intelligence (AI) in which statistical algorithms can be employed to learn from previously generated data and generalize to unseen data. Techniques (including, but not limited to, supervised learning, unsupervised learning, and/or reinforced learning) for generating ML models based on a training set of data are known in the art and, thus, the details thereof have been omitted from this specification in order to allow the reader to focus on the salient aspects of the disclosed embodiments.

In addition to developing required updates and modifications for the P-PCELL for C1 at process 506, the code of the P-PCELL for C1 can be analyzed to determine whether or not it is functional (see process 508). Optionally, success metrics regarding the code (e.g., success percentage) could also be determined at process 508. In any case, if/when the code for the P-PCELL for C1 is determined to be non-functional at process 508, it can be de-bugged (i.e., revised or modified) to ensure that it is functional (see process 510). It should be noted that specific revisions made to the code of the P-PCELL for C1 at process 510 can also be added to the first ML training set (if applicable) to be used during subsequent development of a P-PCELL for a different IC component.

In any case, once the P-PCELL code has been revised, as necessary, at process 510, additional evaluations of the P-PCELL for C1 can be performed. For example, user-customized configurations of the P-PCELL for C1 can be compared with the specifications and GDS files for C1 and, based on results of this comparison, irregularities in the P-PCELL can be detected (see process 512). Such irregularities can include, but are not limited to, any of: inconsistencies in layer and parameter relationships, inconsistencies in parameter range, and missing parameters. These irregularities in the P-PCELL can subsequently be corrected (e.g., the P-PCELL code 241 and/or the CDF files 242, such as callbacks 243, can be revised) (see process 514). It should be noted that specific revisions made to the P-PCELL code and/or CDF files at process 514 can also be added to the first ML training set (if applicable) to be used during subsequent development of a P-PCELL for a different IC component.

Referring again to the flow diagram of FIG. 3, once the P-PCELL for a specific IC component has been evaluated and updated or modified, as necessary, a product-ready parameterized cell (PCELL) for that specific IC component can be included in the PCELL library 111 of the PDK 110 (see process 306 of FIG. 3).

Evaluation of the P-PCELL for a specific IC component as described above at process 304 of FIG. 3 and further illustrated in FIG. 5 allows for early detection of required updates and modifications (e.g., to the DM and/or to parameter ranges, etc.). Thus, the disclosed method accelerates the process of PDK 110 development, improves the quality of the PCELL (including the code thereof) before inclusion in the PDK 110, and increases PCELL productivity. Consequently, when IC designs are developed using PCELLs generated according to the disclosed method, ICs manufactured according to such IC designs will have a higher probability of meeting performance specifications and, thus, a higher yield.

Embodiments disclosed herein may be implemented as a computer system, a computer-implemented method, and/or a computer program product. The computer program product may include a computer readable storage medium (or media) having computer readable program instructions thereon for causing a processor to carry out aspects of the disclosed embodiments.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the disclosed embodiments may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the disclosed embodiments.

Aspects of the disclosed embodiments are described herein with reference to flowchart illustrations and/or block diagrams of methods, apparatus (systems), and computer program products according to disclosed embodiments. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various disclosed embodiments. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

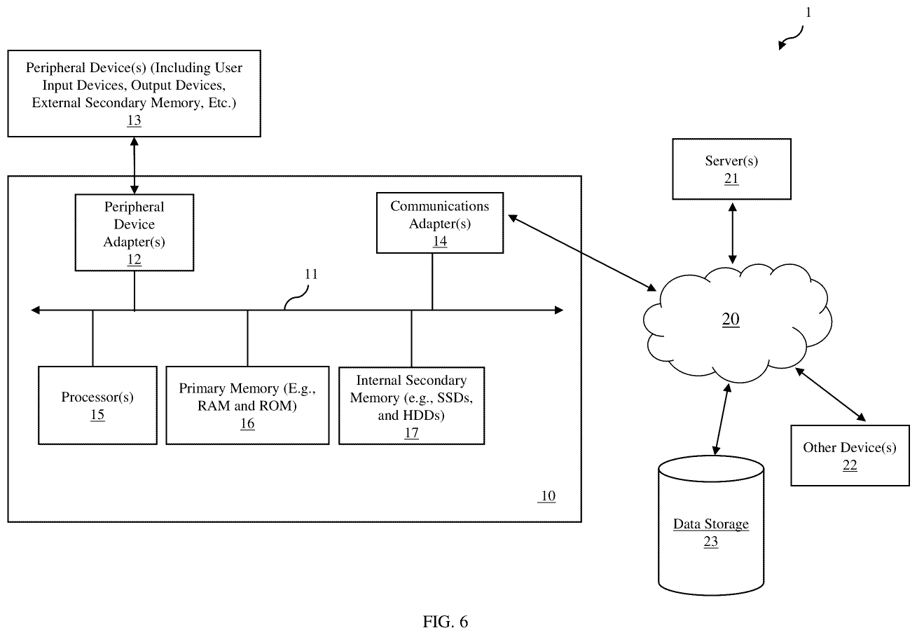

An exemplary hardware environment 1 (i.e., computer system) for implementing aspects of the disclosed systems, methods and computer program products is depicted in FIG. 6. Generally, the hardware environment can include at least one computer 10. Computer 10 can be, for example, a desktop, laptop, tablet, mobile computing device, etc. Computer 10 can include at least one bus 11. Bus 11 can be connected to various other components of computer 10 and can be configured to facilitate communication between those components.

Computer 10 can include various adapters. The adapters can include one or more peripheral device adapters 12, which are configured to facilitate communications between one or more peripheral devices 13, respectively, and the bus 11. Peripheral devices 13 can include user input devices configured to receive user inputs. User input devices can include, but are not limited to, a keyboard, a mouse, a microphone, a touchpad, a touchscreen, a stylus, bio-sensor, a scanner, or any other type of user input device. Peripheral devices 13 can also include additional input devices, such as external secondary memory devices (as discussed in greater detail below). Peripheral devices 13 can also include output devices. The output devices can include, but are not limited to, a printer, a monitor, a speaker, or any other type of computer output device. The adapters can include one or more communications adapters 14 (also referred to herein as a computer network adapters), which are configured to facilitate communications between computer 10 and one or more communications networks 20 (e.g., a wide area network (WAN), a local area network (LAN), the internet, a cellular network, a Wi-Fi network, etc.). Such network(s) 20 can, in turn, facilitate communications between computer 10 and other system components on the network: remote server(s) 21, other device(s) 22 (e.g., computers, laptops, tablets, mobile phones, etc.), remote data storage 23, etc.

Computer 10 can further include at least one processor 15 (also referred to herein as a central processing units (CPU)). Optionally, each CPU 15 can include a CPU cache. Each CPU 15 can be configured to read and execute program instructions.

Computer 10 can further include memory and, particularly, computer-readable storage mediums. The memory can include primary memory 16 and secondary memory. Primary memory 16 can include, but is not limited to, random access memory (RAM) (e.g., volatile memory employed during execution of program operations) and read only memory (ROM) (e.g., non-volatile memory employed during start-up). The RAM can include, but is not limited to, dynamic random access memory (DRAM), static random access memory (SRAM), or any other suitable type of RAM. The ROM can include, but is not limited to, erasable programmable read only memory (EPROM), flash memory, electronically erasable programmable read only memory (EEPROM), programmable read only memory (PROM), or any other suitable type of ROM. Secondary memory can be non-volatile. The secondary memory can include internal secondary memory 17, such as internal solid state drive(s) (SSD(s)) and/or internal hard disk drive(s) (HDD(s), installed within the computer 10 and connected to bus 11. The secondary memory can also include external secondary memory connected to or otherwise in communication with computer 10 (e.g., peripheral devices). The external secondary memory can include, for example, external/portable SSD(s), external/portable HDD(s), flash drive(s), thumb drives, compact disc(s) (CD(s)), digital video disc(s) (DVD(s)), network-attached storage (NAS), storage area network (SAN), or any other suitable non-transitory computer-readable storage media connected to or otherwise in communication with computer 10. The different functions of primary and secondary memory are well known in the art and, thus, the details thereof have been omitted from this specification in order to allow the reader to focus on the salient aspects of the disclosed embodiments.

In some embodiments, program instructions for performing the disclosed method or a portion thereof, as described above, can be embodied in (e.g., stored in) secondary memory accessible by computer 10. When the program instructions are to be executed (e.g., in response to user inputs to computer 10), required information (e.g., the program instructions and other data) can be loaded into the primary memory (e.g., stored in RAM). CPU 15 can read the program instructions and other data from the RAM and can execute the program instructions. In other embodiments, a client-server model can be employed. In this case, computer 10 can be a client and a remote server 21 in communication with computer 10 over a network 20 can provide, to the client, a service including execution of program instructions for performing the disclosed method or a portion thereof, as described above, in response to user inputs computer 10.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system comprising:
a processor; and
at least one storage medium readable by the processor,
wherein the at least one storage medium stores a mapping file and multiple different graphic design system (GDS) files for a specific integrated circuit component,
wherein the at least one storage medium further stores a program of instructions, and
wherein the program of instructions is executable by the processor to cause the processor to perform a method including developing a prototype parameterized cell for the specific integrated circuit component using the GDS files and the mapping file.

2. The system of claim 1, wherein the prototype parameterized cell includes:
code; and
component description format files including parameters, attributes of the parameters, and callbacks.

3. The system of claim 1, wherein the developing of the prototype parameterized cell includes:
performing an analysis of the GDS files using the mapping file; and
based on results of the analysis, identifying each device in the specific integrated circuit component and determining parameters of the specific integrated circuit component and ranges of the parameters, respectively.

4. The system of claim 3,
wherein the at least one storage medium stores a device library,
wherein the performing of the analysis includes:
parsing the GDS files into layers using the mapping file and further into shapes within layers; and
identifying regions in the specific integrated circuit component based on the layers and the shapes within the layers, and
wherein the identifying of each device in the specific integrated circuit component is performed based on the regions and using the device library.

5. The system of claim 4, wherein the determining of the parameters of the specific integrated circuit component and the ranges of the parameters is performed based on the layers, the shapes within the layers, the regions, and each identified device in the specific integrated circuit component.

6. The system of claim 5, wherein the determining of the parameters of the specific integrated circuit component and the ranges of the parameters is performed using a first machine learning model.

7. The system of claim 6, wherein the first machine learning model includes a first machine learning training set including data acquired through evaluation of different prototype parameterized cells.

8. The system of claim 1, wherein the method further includes evaluating the prototype parameterized cell for the specific integrated circuit component including:
receiving test feedback acquired through user-testing of the prototype parameterized cell, wherein the test feedback indicates at least detected design rule checking errors; and
developing updates for the prototype parameterized cell based on the design rule checking errors, wherein the updates include any of design manual updates and parameter range updates.

9. The system of claim 8, wherein the developing of the updates is performed using a second machine learning model.

10. The system of claim 9, wherein the second machine learning model includes a second machine learning training set including data acquired through evaluation of previously developed updates for different prototype parameterized cells.

11. The system of claim 8, wherein the evaluating of the prototype parameterized cell for the specific integrated circuit component further includes:
analyzing code of the prototype parameterized cell to determine whether the code is functional; and
when the code is not functional, revising the code.

12. The system of claim 8,
wherein the at least one storage medium further stores specifications for the specific integrated circuit component, and
wherein the evaluating of the prototype parameterized cell for the specific integrated circuit component further includes:
comparing user-customized configurations of the specific integrated circuit component with the specifications and GDS files for the specific integrated circuit component to detect irregularities in the prototype parameterized cell, wherein the irregularities include any of inconsistencies in layer and parameter relationships, inconsistencies in parameter range, and missing parameters; and
correcting the irregularities in the prototype parameterized cell.

13. A method comprising:
accessing, by a processor from at least one storage medium, a mapping file and multiple different graphic design system (GDS) files for a specific integrated circuit component; and
developing, by the processor, a prototype parameterized cell for the specific integrated circuit component, wherein the prototype parameterized cell is developed based on the GDS files and the mapping file.

14. The method of claim 13, wherein the prototype parameterized cell includes:
code; and
component description format files including parameters, attributes of the parameters, and callbacks.

15. The method of claim 13, wherein the developing of the prototype parameterized cell includes:
performing an analysis of the GDS files including:
parsing the GDS files into layers using the mapping file and further into shapes within layers;
identifying regions in the specific integrated circuit component based on the layers and the shapes within the layers; and
identifying each device within the specific integrated circuit component based on the regions and using a device library; and
determining parameters of the specific integrated circuit component and ranges of the parameters, respectively, based on the layers, the shapes within the layers, the regions, and each identified device in the specific integrated circuit component.

16. The method of claim 15, wherein the determining of the parameters of the specific integrated circuit component and the ranges of the parameters is performed using a first machine learning model including a first machine learning training set including data acquired through evaluation of different prototype parameterized cells.

17. The method of claim 15, further comprising evaluating, by the processor, the prototype parameterized cell for the specific integrated circuit component including:
receiving test feedback acquired through user-testing of the prototype parameterized cell, wherein the test feedback indicates at least detected design rule checking errors; and
developing updates for the prototype parameterized cell based on the design rule checking errors, wherein the updates include any of design manual updates and parameter range updates.

18. The method of claim 17, wherein the developing of the updates is performed using a second machine learning model, and wherein the second machine learning model includes a second machine learning training set including data acquired through evaluation of previously developed updates for different prototype parameterized cells.

19. The method of claim 17, wherein the evaluating of the prototype parameterized cell for the specific integrated circuit component further includes:
analyzing code of the prototype parameterized cell to determine whether the code is functional;
when the code is not functional, revising the code;
comparing user-customized configurations of the specific integrated circuit component with specifications and GDS files for the specific integrated circuit component to detect irregularities in the prototype parameterized cell, wherein the irregularities include any of inconsistencies in layer and parameter relationships, inconsistencies in parameter range, and missing parameters; and
correcting the irregularities in the prototype parameterized cell.

20. A computer program product comprising a non-transitory computer readable storage medium having a program of instructions embodied therewith, wherein the program is executable by a processor to cause the processor to perform a method and wherein the method comprises:
accessing, from at least one storage medium, a mapping file and multiple different graphic design system (GDS) files for a specific integrated circuit component; and
developing a prototype parameterized cell for the specific integrated circuit component, wherein the prototype parameterized cell is developed using the GDS files and the mapping file.
